(19) United States
(12) Patent Application Publication
(10) Pub. No.: US 2015/0286006 A1
(43) Pub. Date: Oct. 8, 2015

(54) HIGH EFFICIENCY VERTICAL OPTICAL COUPLER USING SUB-WAVELENGTH HIGH CONTRAST GRATING

(71) Applicant: THE REGENTS OF THE UNIVERSITY OF CALIFORNIA, Oakland, CA (US)

(72) Inventors: Connie Chang-Hasnain, Palo Alto, CA (US); Li Zhu, Berkeley, CA (US); Vadim Karagodsky, Berkeley, CA (US); Weijian Yang, Berkeley, CA (US)

(73) Assignee: THE REGENTS OF THE UNIVERSITY OF CALIFORNIA, Oakland, CA (US)

(21) Appl. No.: 14/055,029

(22) Filed: Oct. 16, 2013

Related U.S. Application Data
(63) Continuation of application No. PCT/US2012/035615, filed on Apr. 27, 2012.
(60) Provisional application No. 61/480,467, filed on Apr. 29, 2011.

(51) Int. Cl. G02B 6/34; G02B 5/18; G02B 6/12; H01L 31/054; H01S 5/125; H01S 5/343; H01S 5/347; G02B 6/42; H01S 5/34

(52) U.S. Cl. CPC G02B 6/34; G02B 6/4214; G02B 6/4206; G02B 5/1809; G02B 6/4298; G02B 6/12004; G02B 6/12007; H01S 5/3402; H01S 5/125; H01S 5/34333; H01S 5/347; H01L 31/0543

(57) ABSTRACT

A vertical optical coupler which redirects light transmission in response to the interaction between a sub-wavelength high contrast grating (HCG) having a plurality of spaced apart segments of grating material which is optically coupled to a waveguide. For a selected set of material, grating geometry, gaps and spacing, the light directed at a normal incidence into the optical coupler is angularly displaced in traveling in the optical waveguide, while light directed along the optical waveguide is angularly displaced in being output at normal incidence from the optical coupler. The coupler is integrated into a number of device embodiments, including: a coupler between angularly displaced waveguides, lasers, light emitting diodes (LEDs) and solar cells.

### CROSS-REFERENCE TO RELATED APPLICATIONS

This application is a 35 U.S.C. §111(a) continuation of PCT international application number PCT/US2012/035615 filed on Apr. 27, 2012, incorporated herein by reference in its entirety, which is a nonprovisional of U.S. provisional patent application Ser. No. 61/480,467 filed on Apr. 29, 2011, incorporated herein by reference in its entirety. Priority is claimed to each of the foregoing applications.

The above-referenced PCT international application was published as PCT International Publication No. WO 2012/149441 on Nov. 1, 2012, and republished on Jan. 17, 2013, which publications are incorporated herein by reference in their entireties.

### STATEMENT REGARDING FEDERALLY SPONSORED RESEARCH FOR DEVELOPMENT

This invention was made with Government support under Grant Number N00244-09-1-013 awarded by the Department of Defense (DOD) under the National Security Science and Engineering Faculty Fellowship (NSSEFF) Program. The Government has certain rights in the invention.

### INCORPORATION-BY-REFERENCE OF MATERIAL SUBMITTED ON A COMPACT DISC

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. §1.14.

### BACKGROUND OF THE INVENTION

1. Field of the Invention

This invention pertains generally to optical transmission, and more particularly to an optical coupler for changing the direction of light transmission.

2. Description of Related Art

High-density photonic integrated circuits (PICS) are important to integrate various optical functionalities in one single chip for many applications, ranging from communications, sensing, display, to system-on-a-chip and lab-on-a-chip applications. These devices, by and large, utilize light guided by waveguides in the direction parallel to the wafer surface, known as the in-plane direction. Devices are cascaded longitudinally (in the direction of light propagation) or laterally (orthogonal to light propagation) to achieve higher levels of functionalities. Various material platforms have been reported, including InP-based material, silicon and silicon-on-insulator (SOI), various organic materials, and so forth. Efficient coupling of a surface-normal propagating light beam, such as from an output of an optical fiber or free-space optics, or a device, (e.g. lasers such as vertical cavity surface emitting lasers (VCSEL)), with PICS is especially desirable.

However, conventional second order gratings have limited efficiency, often significantly below 25% in each in-plane direction. Some approaches propose adding reflection DBRs or by using slanted gratings. However, those approaches can make fabrication complicated, and perhaps too complicated for practical manufacture.

Accordingly, a need exists for an optical coupling means which can couple and redirect light at high efficiencies. The present invention fulfills that need and overcomes shortcomings of prior coupling technologies.

### BRIEF SUMMARY OF THE INVENTION

A vertical optical coupler with high coupling efficiency using a sub-wavelength high contrast grating (HCG), and a number of novel device designs into which the vertical optical coupler is integrated, are described. An HCG is a single-layer sub-wavelength grating in which the grating high-index bars are completely surrounded by a low-index material. It has been demonstrated that high-Q resonances and high reflectivity can be beneficially achieved under proper design of grating dimensions. For regular grating couplers, when the period Λ is equal to wavelength, the surface normal incident light couples into the in-plane waveguide. By utilizing the resonance nature of HCG, the coupling efficiency from vertical incidence to in-plane waveguide can be increased to a total of at least 92% in both in-plane propagation directions (combined). The inventive coupler can be used in the reverse direction, with input received from an in-plane waveguide and directed to the vertical direction as well. Efficiencies of greater than 90% are achieved for both single-side incidence and double-side incidence. Various inventive devices incorporating the vertical optical coupler are presented.

Further aspects of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1 is a schematic of a “vertical to in-plane” coupler according to an embodiment of the present invention.

FIG. 2 is a schematic of an “in-plane to vertical” coupler with symmetrical incidence according to an embodiment of the present invention.

FIG. 3 is a schematic of a single-side “in-plane to vertical” coupler according to an embodiment of the present invention.

FIG. 4A and FIG. 4B are graphs of operating modes utilized according to an embodiment of the present invention, showing first through third modes in FIG. 4A, and an overall mode profile at the output plane z=t in FIG. 4B.

FIG. 5 is a graph of HCG surface normal reflectivity utilized according to an embodiment of the present invention.

FIG. 6 is a graph of a mode dispersion relationship utilized according to an embodiment of the present invention.

FIG. 7A and FIG. 7B are graphs of vertical to in-plane coupling, utilized according to an embodiment of the present invention, showing field distribution in FIG. 7A, and coupling efficiency in FIG. 7B.

FIG. 8A and FIG. 8B are graphs of coupling utilized according to an embodiment of the present invention, showing symmetrical in-plane incidence to vertical coupling field distribution in FIG. 8A, and coupling efficiency in FIG. 8B.

FIG. 9A and FIG. 9B are graphs of in-plane characteristics utilized according to an embodiment of the present invention, showing waveguide field distribution for the case of in-plane reflection in FIG. 9A, and in-plane reflectivity in FIG. 9B.

FIG. 10A through FIG. 10C are graphs of efficiency spectrum in response to different HCG thickness utilized according to an embodiment of the present invention, showing in-plane reflection (−x direction) in FIG. 10A, vertical coupling (+z direction) in FIG. 10B, and in-plane transmission (+x direction) in FIG. 10C.

FIG. 11A and FIG. 11B are graphs of single side in-plane incidence to vertical coupling field distribution in FIG. 11A, and coupling efficiency in FIG. 11B utilized according to an embodiment of the present invention.

FIG. 12 is a schematic of light being turned in a hollow-core waveguide (HW) utilizing vertical couplers according to an embodiment of the present invention.

FIG. 13 is a schematic of light being turned in a hollow-core waveguide (HW) utilizing side-coupling according to an embodiment of the present invention.

FIG. 14 is a schematic of connecting two HCG hollow core waveguide couplers according to an embodiment of the present invention to turn light.

FIG. 15 is a schematic of an HCG multiplexer according to an embodiment of the present invention.

FIG. 16 is a schematic of an HCG demultiplexer according to an embodiment of the present invention.

FIG. 17 is a schematic of vertical incidence to single side in-plane waveguide coupling according to an embodiment of the present invention.

FIG. 18 is a schematic of parallel waveguide coupling according to an embodiment of the present invention.

FIG. 19 is a schematic of an HCG vertical coupler and reflector for surface-emitting quantum cascade laser according to an embodiment of the present invention.

FIG. 20 is a schematic of an HCG reflector as cavity mirror in GaN laser diode according to an embodiment of the present invention.

FIG. 21 is a schematic of HCG light extraction for GaN light emitter diode according to an embodiment of the present invention.

FIG. 22 is a schematic of an HCG light collector for a solar cell according to an embodiment of the present invention.

### DETAILED DESCRIPTION OF THE INVENTION

1. High Contrast Grating Vertical Coupler Structure

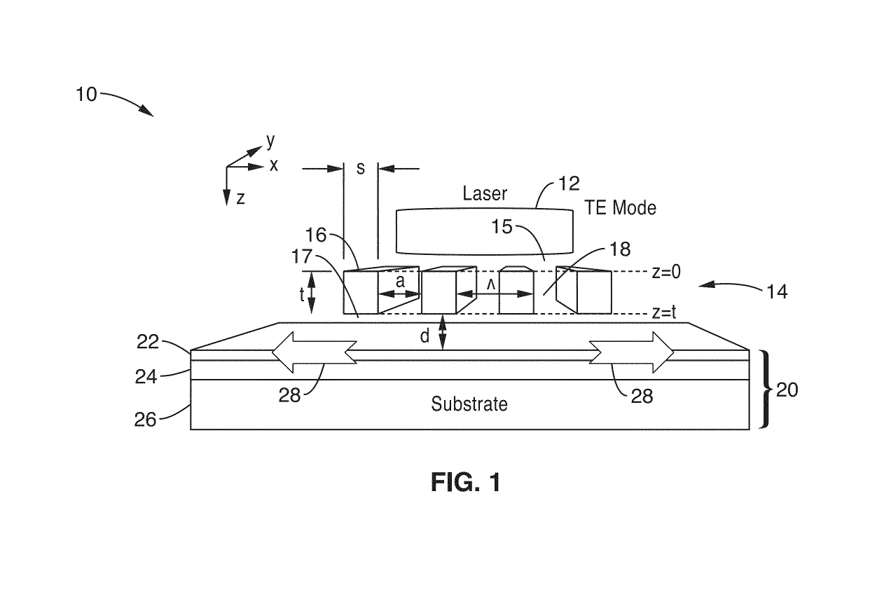

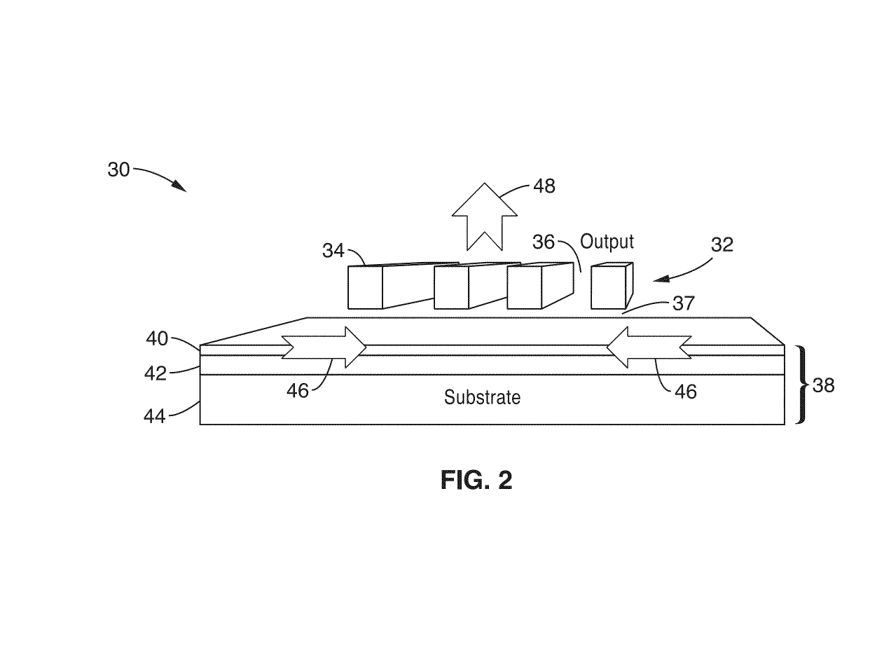

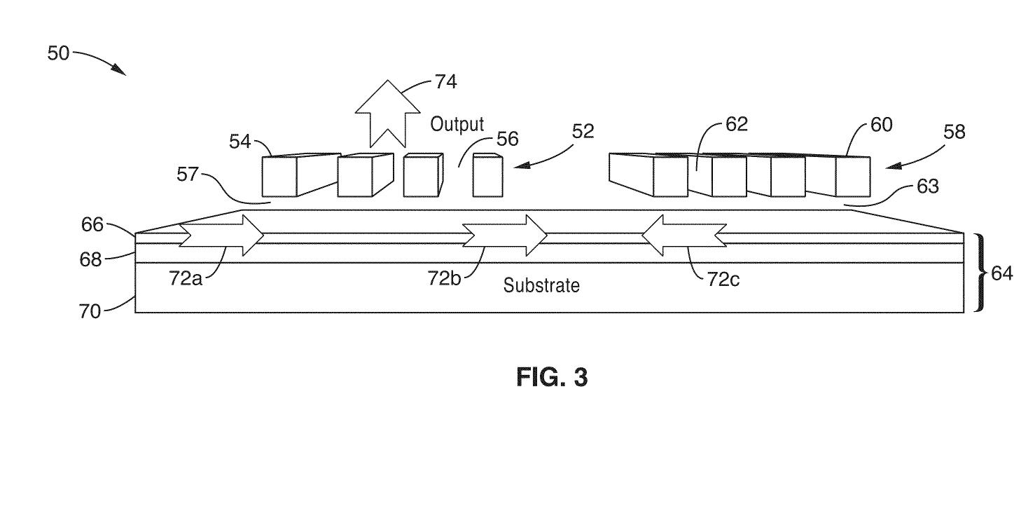

FIG. 1 through FIG. 3 illustrate different operations of the inventive vertical coupler which can couple light from a vertical light source into both directions of a horizontal waveguide (FIG. 1), or from both directions of the horizontal waveguide to the vertical direction (FIG. 2), or utilize a single side operation of the vertical coupler in which light is preferentially coupled to or from one direction of the waveguide (FIG. 3). The optical coupler thus angularly displaces light transmission passing either way through the coupler. These operations of the vertical optical coupling are described in greater detail in the following sections. In one embodiment, the vertical coupler comprises a sub-wavelength high contrast grating (HCG) configured with proper grating dimensions and spacing for interoperation with a waveguide whose characteristics match the HCG. The period of the HCG preferably should be close to, or the same as, periodicity of the field profile for a specific waveguide mode in the propagation direction (i.e., propagation constant).

In the embodiment illustrated in FIG. 1, a laser light source 12, comprising a laser (which, for example, can be a VCSEL or edge emitting laser), is shown coupled to a HCG 14, having periodic spaced apart segments of grating material 16 of width (s) and thickness (t), with a spacing 18 of distance (a) between segments and period Λ. Although the embodiments address the use of a VCSEL, it should be appreciated that a laser or edge emitting laser can be generally substituted. The HCG is positioned with a gap 15 beneath the VCSEL, and a gap 17 above the waveguide 20.

The gap size is a design parameter which can influence power coupling efficiency and its spectral width from laser into waveguide. The gap size design can be optimized by finite-difference time-domain (FDTD) simulations or numerical analysis. A typical value is in the range from 10 nm to about 1,500 nm, depending on the refractive indices of the material used for the gap and the HCG, as well as the wavelength of interest. In the range given above, there exists an optimum value range with which a high coupling efficiency and broad spectral width is achieved. As the gap increases and reduces from the optimum range, both coupling efficiency and spectral width are reduced.

In this example embodiment, waveguide 20 is shown comprising an in-plane silicon-on-insulator (SOI) waveguide having a waveguide layer 22 and buried oxide layer 24. The buried oxide layer should be sufficiently thick that the light is guided by the waveguide 22 and does not experience significant leakage into the silicon substrate. A plane wave with the E-field polarized in the y-direction (hereinafter TE polarization) propagates in the z-direction (downward) from VCSEL 12 towards HCG 14. The three physical parameters that select the characteristics of the HCG are period (Λ), thickness (t) and duty cycle (η). The period (Λ) of sub-wavelength high contrast grating should be smaller than the working wavelength while the thickness can be larger. The duty cycle (η) is defined herein as the ratio of grating bar width to period (s/Λ). In this example, an in-plane SOI waveguide is utilized and placed beneath the HCG, separated by a gap 17 denoted by (d). In this example, the silicon waveguide thickness is 0.1 μm, SiO₂ layer thickness is 1.35 μm. Based on such structure, the light incidence from +z direction is coupled into the waveguide in both +x and −x directions 28 symmetrically. It is also seen in the figure that the top surface of the HCG waveguide is designated as z=0, while the bottom is at z=t .

In FIG. 2, operation of the vertical coupler is illustrated in example embodiment 30 with light symmetrically incident along the waveguide being output vertically. The sub-wavelength HCG 32 can have the same parameters as described for FIG. 1 with grating segments 32, and spacing 34, and gap 37 over the waveguide 38, such as having a waveguide layer 40 and buried oxide layer 42 and a substrate layer 44. Light 46 is shown traversing the waveguide 38 and coupled through the vertical optical coupler 32, with its interaction with the waveguide to direct the light in direction 48.

In FIG. 3, operation of the vertical coupler is illustrated in example embodiment 50 with light transmission through waveguide 64 being blocked from vertical coupler 52 for vertical output 74, by an in-plane reflector 58. The vertical coupler 52 can be configured with the same parameters as described for FIG. 1 with regard to spaced art segments of grating material 54, spacing 56, and gap 57 over the waveguide 64. The waveguide 64 is illustrates by way of example and not limitation with a waveguide layer 66, buried oxide layer 68 and a substrate layer 70. In the figure, arrow 72a depicts light input to the waveguide, with arrow 72b depicting transmission light that cannot be coupled vertically in a single pass. Arrow 72c represents the reflected light of 72b through in-plane reflector 58. The large vertical arrow 74 represents the total vertically out-coupling light. The reflector 58 also comprises segments of grating material 60, spaces 62, and is positioned with a gap 63 separating it from waveguide 64. HCG parameters for reflector 58 differ from that of the vertical optical coupler to provide efficient and broadband reflection.

The coupler design procedure is as follows. The first step is to determine the HCG period Λ. The goal is to couple a down-propagating plane wave, with the E-field polarized in y-direction into the fundamental TE mode of the Si waveguide (E-field in the same direction). It will be appreciated that an HCG can be considered as a (short) slab waveguide array supporting modes propagating in the z-direction.

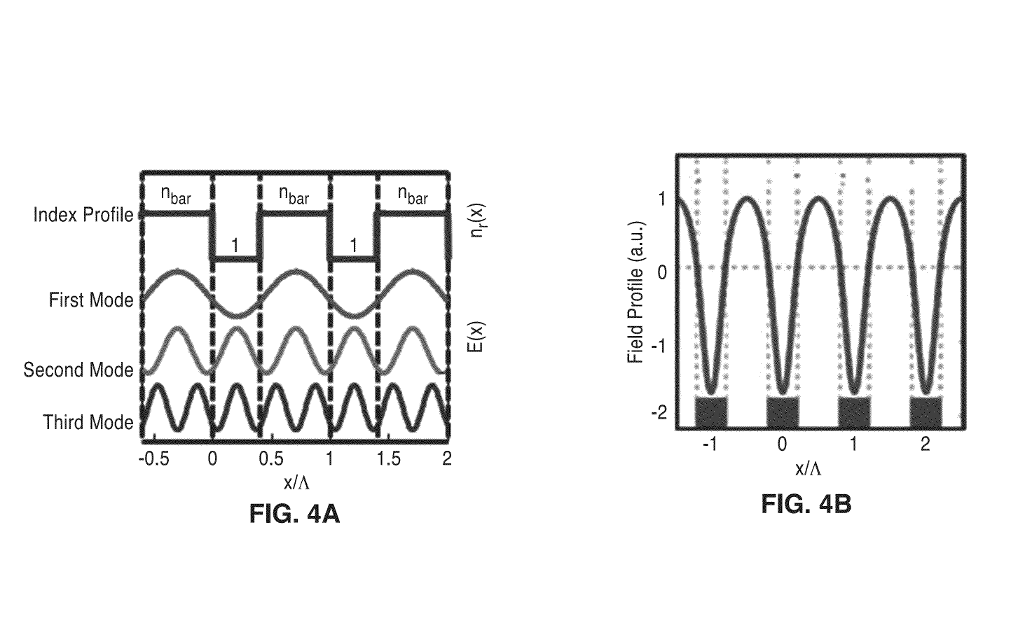

FIG. 4A and FIG. 4B depict mode characteristics of a high contrast grating utilized in the vertical optical coupler. In FIG. 4A, in-plane lateral mode profiles for the first three modes of propagation are seen. Due to the large index contrast, there exists a wide wavelength range where the HCG supports exactly two propagating modes, while the third and higher modes are evanescent in z and are bound to input and output surfaces of HCG (surface modes). These first two modes propagate in the z-direction with different propagation constants, β₁ and β₂. At the input and output planes, z=0 and z=t, respectively, the two modes are reflected not only back to themselves, but also couple into each other's reflections, resulting in a mixing of the two modes. The propagation wave-numbers adjusted for the mode cross-coupling are denoted herein as β′₁ and β′₂ . Most importantly, due to the sub-wavelength period, the two modes do not couple into any diffraction order other than the fundamental one, which is a surface normal propagating plane wave.

In FIG. 4B, the net field profile at the existing planes is seen having a periodic spatial variation equal to the HCG period. The high coupling can be anticipated when this periodicity is matched to the propagation constant of the Si/SiO₂ waveguide mode, denoted as βₓ since it propagates in x-direction. The first step for the vertical coupler is therefore calculating the effective index η_{eff} of Si/SiO₂ waveguide, where η_{eff} is βₓλ₀/2π and λ₀ is the free space wavelength. This leads to the determination of the period of HCG, Λ=2π/βₓ=λ₀/η_{eff}.

Next, HCG thickness is determined by finding the condition when β′₁t and β′₂t are a multiple of 2π, which is the condition in which the two modes are in resonance, whereby the field inside the grating under this condition is accordingly enhanced.

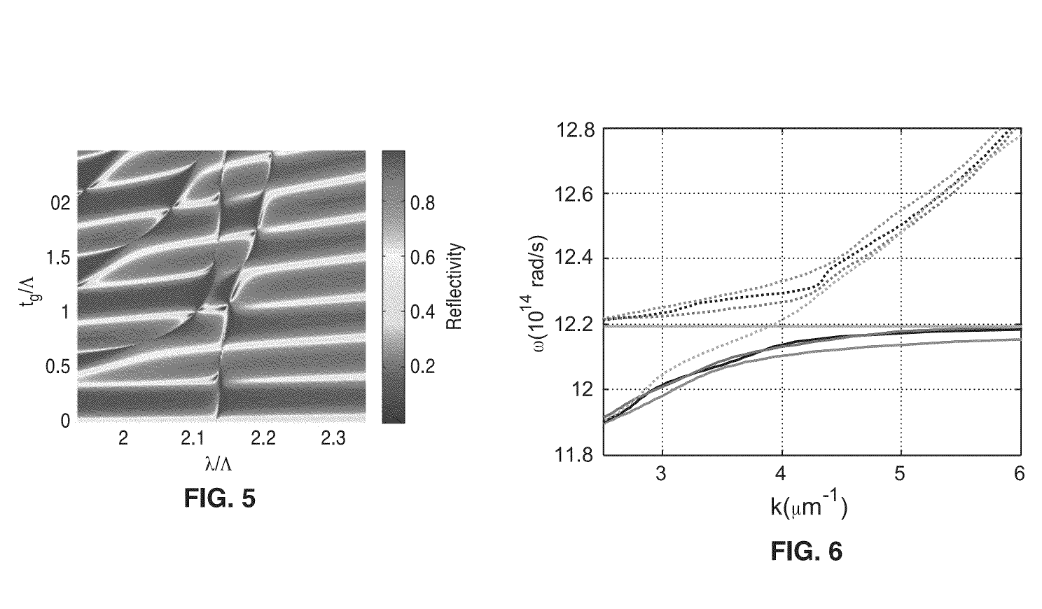

FIG. 5 depicts HCG surface normal reflectivity, indicating that for a given λ₀ and Λ, there are multiple sets of t and η pairs that satisfy this condition.

FIG. 6 depicts the dispersion relationship of one such resonance mode, in which the four sets of dotted lines represent HCG resonance modes, while the solid lines represent coupled waveguide modes. The flat solid line and lower dotted line depict the mode without coupling. The other lines illustrate the use of an air gap (d) of 0.25 μm, 0.30 μm and 0.35 μm, respectively. Toward the middle of the graph the dotted line curves are seen in order of air gap spacing, with 0.35 μm seen as the lowest dotted line, and 0.25 μm as the uppermost dotted line. On the other hand, the Si waveguide mode propagating in the x direction can be represented by a straight horizontal line in the dispersion curve. By changing the gap between HCG and Si waveguide, d, the HCG resonance mode couples with the waveguide mode, causing the crossed dispersion lines to repel against each other. The stronger the coupling is, the wider the bandgap of the forbidden zone. At the center of the forbidden zone, there is no longer allowed real values for k_{z}, indicating the wave is forbidden to propagate in the vertical direction and all energy is transferred to in-plane propagation.

2. Coupler Performance

2.1 Vertical to In-Plane Coupler

At the wavelength of 1.55 μm for this example embodiment, the waveguide effective index is 2.13. The HCG perturbs the effective index of the waveguide underneath to 2.14. Based on the design principle described above, the following parameters were chosen: period Λ=0.724 μm, HCG thickness t=0.96 μm, duty cycle η=0.61 and air gap thickness d=0.25 μm.

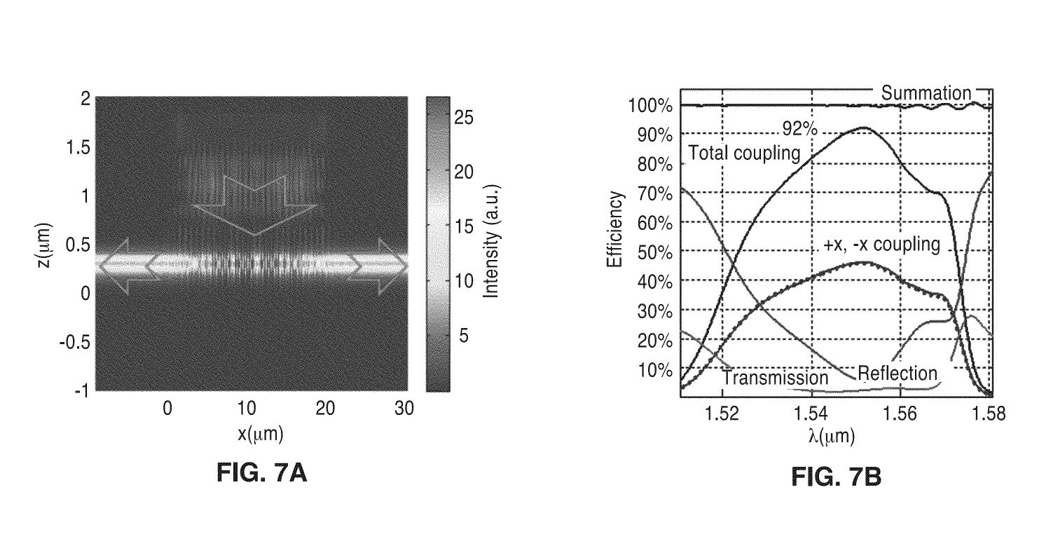

FIG. 7A and FIG. 7B depict results of a finite difference time domain (FDTD) simulation performed to test the design. In FIG. 7A, the intensity distribution shows the coupling effect, in which it can be clearly seen that the field inside the waveguide under the HCG is enhanced and the surface normal incident light is coupled into the waveguide. In FIG. 7B, coupling efficiency is seen for each propagation direction as a function of wavelength. The highest coupling efficiency for this example is 46% and the coupling wavelength is 1.552 μm . Therefore, in the combination of both +x and −x directions, 92% of incident energy was coupled into the waveguide. The remaining 8% was leakage due to the limited HCG width. The 1 dB and 3 dB coupling bandwidths were found to be 30 nm and 50 nm, respectfully, which is substantially wide and readily makes this device useful for WDM application. The bandwidth is determined by the band gap of the forbidden zone, which can be tuned by the spacing between the HCG and the waveguide, as was shown previously in regard to FIG. 6. Therefore, wider or narrower bandwidth can be achieved by tuning the air gap and the corresponding HCG dimension.

2.2 Coupler from Symmetrical In-Plane Incidence to Vertical Output

Based on reciprocity, it can be expected that the symmetrical light incidence from two sides of the waveguide can be coupled into the vertical direction with high efficiency as well, as shown in the schematic of FIG. 2.

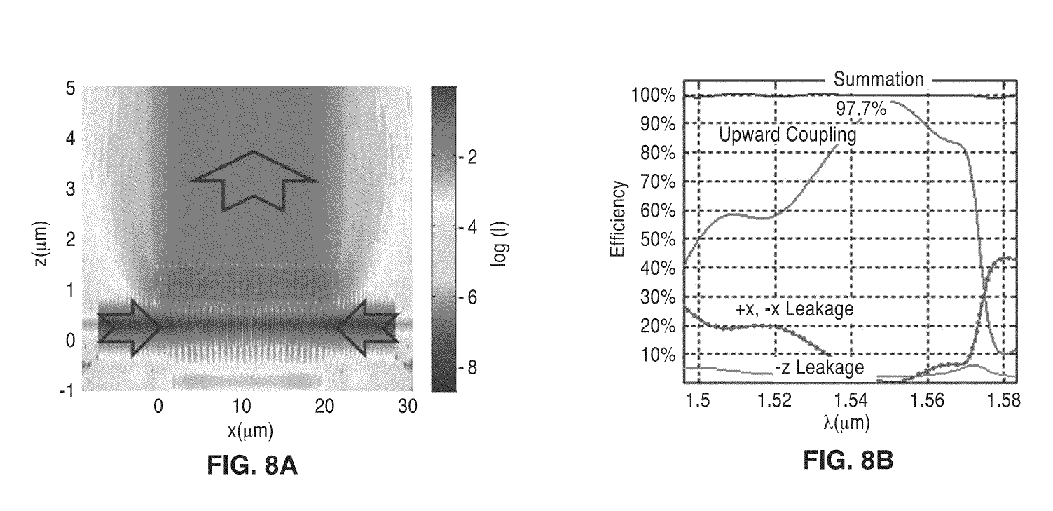

FIG. 8A through FIG. 8D depict FDTD simulation results for coupling light from two sides of the waveguide into the vertical direction. The dimensions in this configuration are the same as the vertical to in-plane coupler. In this simulation, two mode matched light sources are positioned at the waveguide symmetrically to HCG. In FIG. 8A the field distribution is plotted in a log scale, while FIG. 8B shows the coupling efficiency with plots for −z leakage (bottom line) +x, −x leakage (trough-shaped curve), upward coupling (peaked curve), and the combination (summation). At the wavelength of 1.551 μm, the highest coupling efficiency is found to be 97.7%. The 1 dB and 3 dB bandwidths are 38 nm and 70 nm, respectively.

2.3 Coupler from Single Side In-Plane Incidence to Vertical Output

For the single side in-plane incidence case, previously described in FIG. 3, to prevent optical transmission passing through the waveguide, an in-plane reflector is integrated into the device. By changing the HCG thickness t with the other dimensions fixed as in the previous designs, a broad band high efficiency in-plane reflector can be designed.

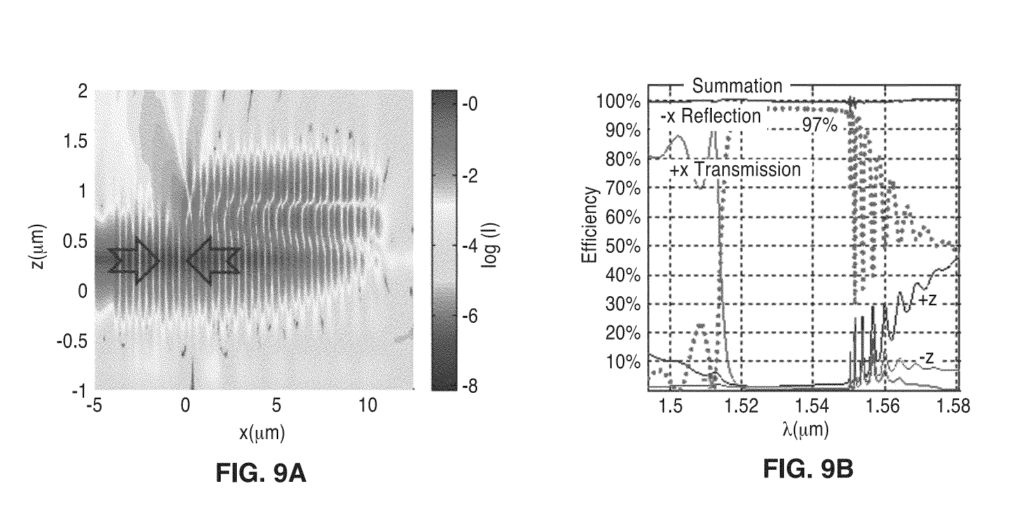

FIG. 9A and FIG. 9B depict simulated waveguide field distribution and in-plane reflectivity, respectively. The field distribution of in-plane reflectivity in FIG. 9A is shown in a log scale, for a device with HCG thickness t at 0.495 μm, a period λ of 0.724 μm, and duty cycle η at 0.61. FIG. 9B depicts the reflectivity spectrum, with the highest reflectivity in this test being 97% with a bandwidth of 30 nm. It will be noted that by varying the HCG thickness in the simulation, the HCG expresses different behaviors.

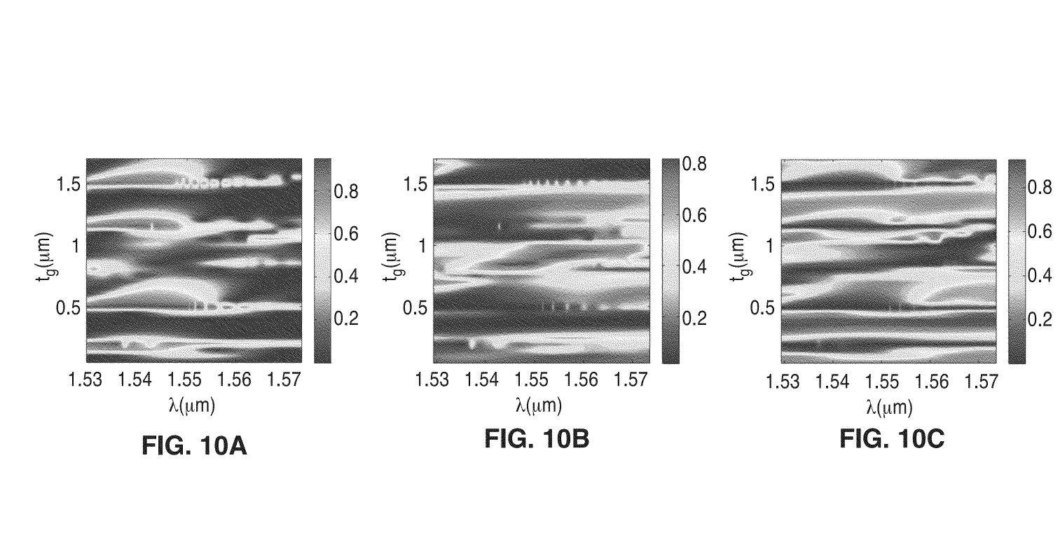

FIG. 10A through FIG. 10C, respectively, depict that the light can be reflected backward in the −x direction shown in FIG. 10A, coupled upwardly in the +z direction shown in FIG. 10B, or transmitted through in the +x direction shown in FIG. 10C across a range of different HCG thicknesses, with these transformations observed with respect to grating period.

In the above example, the HCG coupler and in-plane reflector grating were selected with the same thickness, but having different periods and duty cycles. By increasing the duty cycle, the anti-crossing behavior seen in FIG. 5 can be shifted to smaller HCG thicknesses. In FIG. 5, sharp reflectivity changes indicate the resonance conditions of specific modes. At the center, two modes which are supposed to intersect with each other repel at the crossing point, and is referred to as the anti-crossing behavior. The coupler HCG of the example embodiment has a thickness of 0.495 μm, period 0.715 μm, and a duty cycle of 0.69.

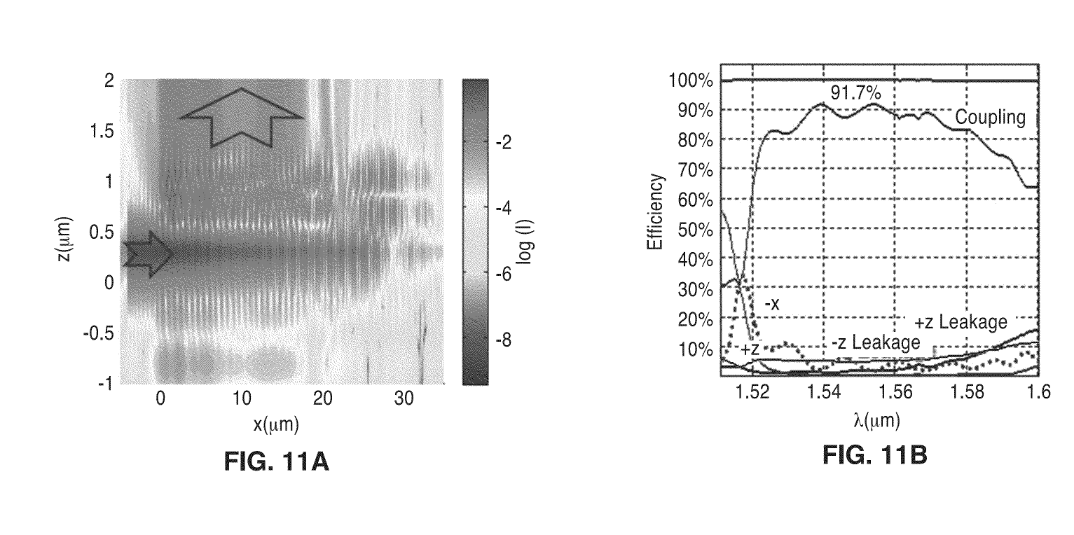

FIG. 11A and FIG. 11 B depict, respectively, coupling field distribution and the coupling efficiency spectrum for this configuration. The highest coupling efficiency observed in this example embodiment was 91.7% at a wavelength of 1.554 μm, with the 1 dB bandwidth at 70 nm.

3. Applications

3.1. Integration of Vertical Coupler with Hollow Core Waveguides

Notwithstanding the numerous beneficial configurations described in the preceding sections, the inventive vertical optical coupler also provides wide applicability in the context of hollow-core waveguides (HWs). It will be appreciated that a wide range of applications exist for these hollow-core waveguides (HWs), including applications in gas sensing and gas-based nonlinear optics. With the elimination of core material, the problems with nonlinearity, dispersion effects and scattering losses in traditional SiO₂, Si or III-V waveguides can be drastically reduced. Utilizing chip-scale HWs opens up a new range of on-chip applications, such as optical buffers, optical signal processors, and RF filtering. Although integrated HWs can achieve a low propagation loss for the straight session, there is usually a relatively large light leakage when the waveguide bends. At the bending region, the sidewall reflection reduces, and thus large radiation losses can arise, in particular with integrated HWs. The small footprint of integrated optics requires unavoidably tight packing of the waveguides and sharp turns. This would introduce high loss as the bending loss increases exponentially with the decrease of the radius of curvature. These losses have imposed significant limitations on the application of integrated HWs. Use of the inventive vertical coupler can solve this problem by bridging two adjacent HWs without the need of a sharp bend.

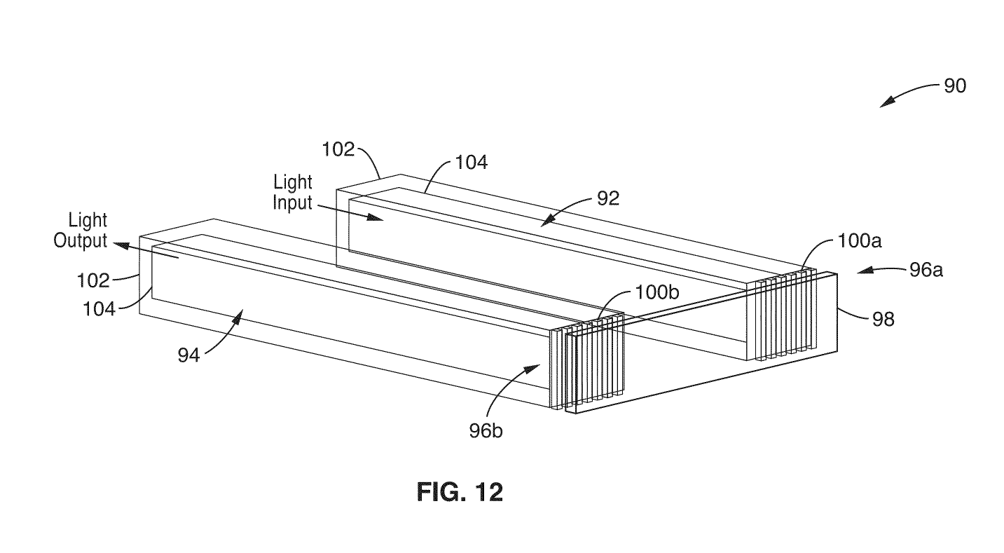

FIG. 12 through FIG. 14 illustrate example embodiments utilizing vertical couplers with waveguides. The hollow core waveguides can be of any desired types, such as metal HWs, distributed Bragg reflection type HWs, anti-resonant HWs, HCG HWs, or other form of HW. These examples illustrate coupling so that the light is turned a full 180 degrees, although the teachings are applicable to turning light through other angular displacements. Because the coupler can be designed to have coupling with any angle, the stripe waveguide 98 and HCG HWs 92 and 94 can be configured to any required angle and work with the corresponding couplers.

In the embodiment 90 of FIG. 12, two HWs are seen 92, 94 having exterior 102 surrounding an interior hollow light guide region 104. At the end of each of these HWs are vertical couplers 96a, 96b, in a butt-coupling arrangement, that are in turn interconnected with each other by a strip waveguide 98. An HCG 100a, 100b are seen in each vertical coupler upon which light has normal incidence from HWs 92, 94 to the vertical coupler. Through the vertical coupler, light can be transformed from the HWs to the stripe waveguide. The propagation direction of the light thus changes 90 degrees at each vertical coupler. The first vertical coupler 96a directs light from a first waveguide 92 into a stripe waveguide 98, while a second vertical coupler 96b transforms the light back onto the adjacent HW 94. In this case, a virtually sharp turn is made without any sharp bends. With the high efficiency of the vertical coupler, the loss for the whole transformation can be small, on the order of 10% or less.

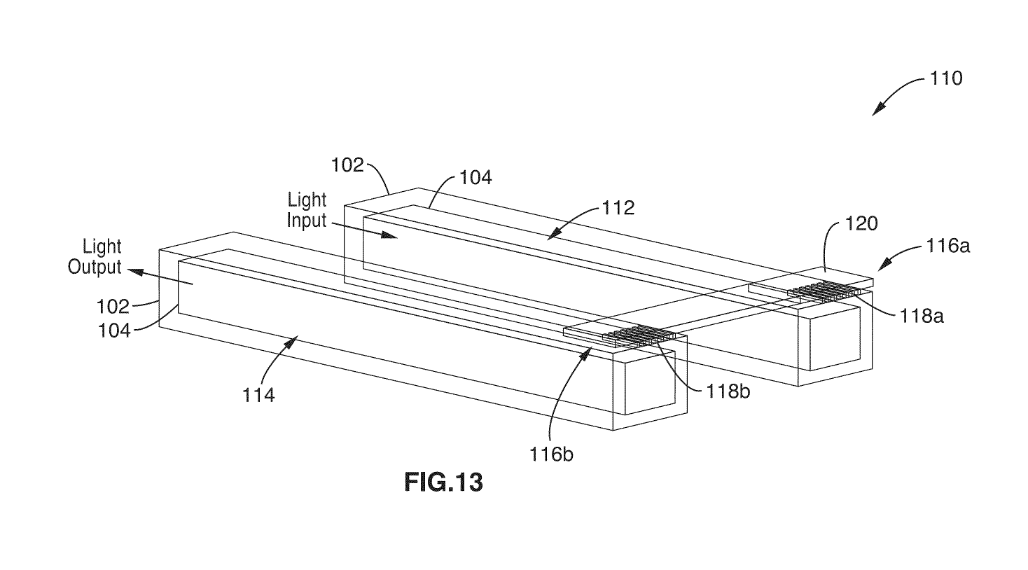

FIG. 13 illustrates an alternative HW light bending technique to the above, utilizing the vertical coupler configured in a side-coupling embodiment 110. A first waveguide 112 and second waveguide 114 are shown having an exterior 102 with hollow waveguide interior 104. The grating 118a, 118b of the vertical couplers 116a, 116b are placed on top of the waveguides 112, 114 with a stripe waveguide 120 connecting the vertical couplers. This and other embodiments of the invention may also be equally realized by replacing the stripe waveguide with other forms of waveguides, such as HCG waveguide, or hollow waveguides. With a proper design, light can be coupled upwards to the stripe waveguide, and then downwards to the adjacent HW. It should be appreciated that this configuration may be particularly well-suited to simplified fabrication processing.

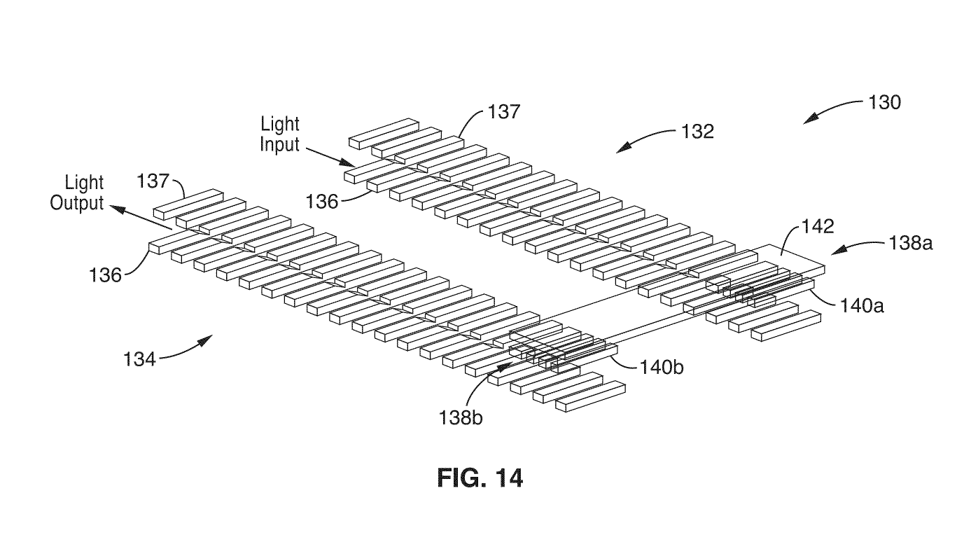

FIG. 14 illustrates an embodiment 130 in which the vertical coupler is utilized with HCG HWs 132, 134, to which it may be even more beneficially coupled. It will be appreciated that HCG HWs represent another class of hollow-core waveguide, with the HCG configured as high reflection mirrors, and light is thus confined between opposing layers 136, 137 of HCGs. This form of waveguide has an extremely low propagation loss, and lateral confinement can be achieved by choosing different periods and duty cycles for the core and cladding region. A first vertical coupler 138a with its HCG 140a is shown integrated with first HCG HW 132, with light coupled through a stripe waveguide 142 to a second vertical coupler 138b, with its HCG 140b, coupled to a second HCG waveguide 134. It will be appreciated that the HCGs at the end of the waveguide can be designed as a vertical coupler to transform the light upwards to the stripe waveguide, or downwards from the stripe waveguide. The transition between the waveguide and the coupler can be designed to be smooth, and this ensures a minimum loss. It would appear that this arrangement can provide a most beneficial combination to replace traditional lossy light bending arrangements.

3.2. WDM Multiplexer and Demultiplexer

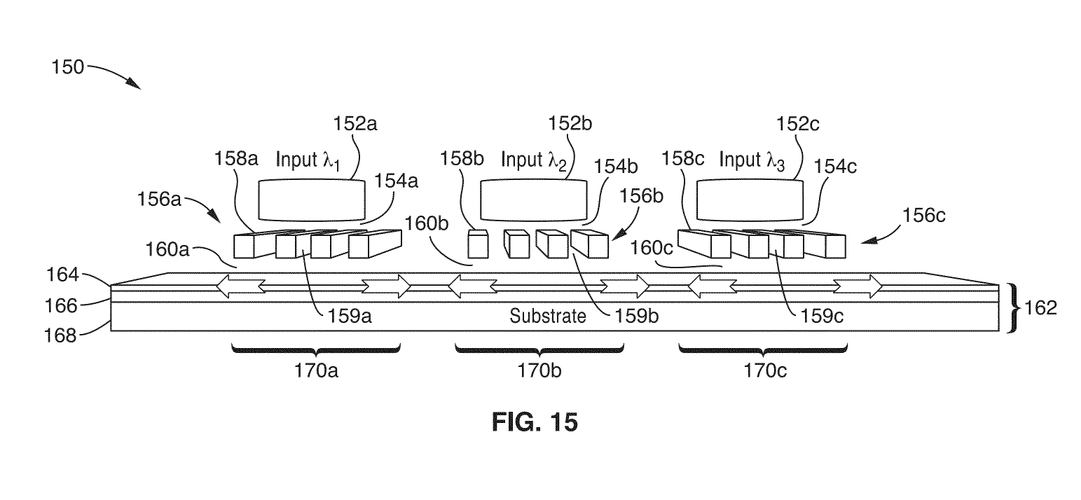

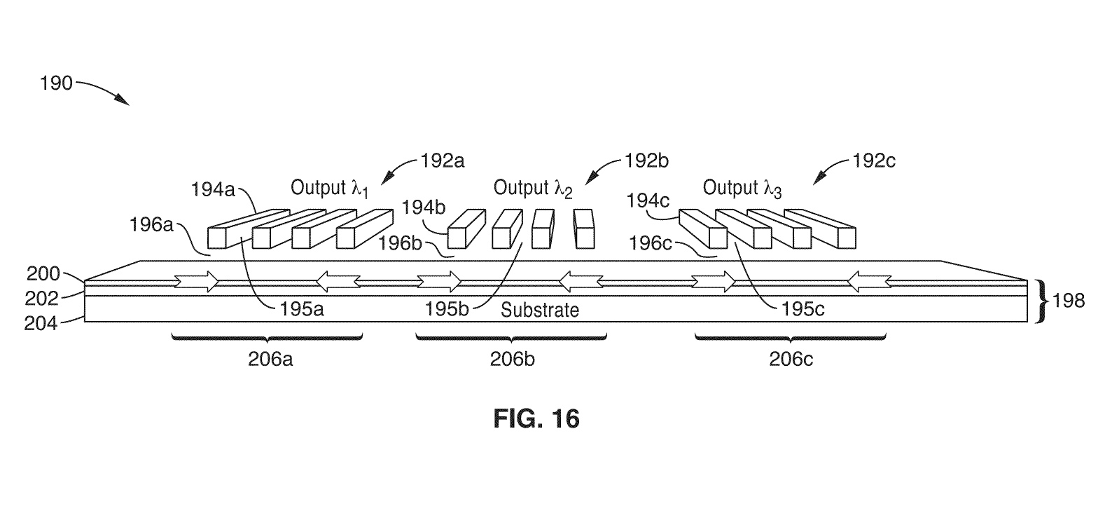

FIG. 15 and FIG. 16 illustrate utilizing the inventive HCG vertical coupler for multiplexing and demultiplexing in a WDM system. In the multiplexer embodiment 150 of FIG. 15, outputs from a plurality of VCSELs 152a, 152b and 152c with different wavelengths (λ₁, λ₂, λ₃) are coupled through the inventive vertical optical coupling into a waveguide 162. It will be appreciated that the multiplexor and the demultiplexer of these figures are shown having three inputs/outputs, for the sake of simplicity of illustration, however, the technique can be utilized with any desired number of inputs/outputs, respectively. It should also be appreciated that each vertical coupler is configured for its particular working wavelength, and that by optimizing HCG parameters, the crosstalk arising between different wavelengths can be essentially eliminated.

It will be seen from the figure that inputs 152a, 152b, 152c are directed through gap 154a, 15b, 154c to an HCG 156a, 156b, 156c, containing segments 158a, 158b, and 158c along with spaces 159a, 159b, 159c. Vertical coupling between HCG 156a, 156a, 156c is through gap 160a, 160b, 160c with a waveguide 162 having a waveguide layer 164, a buried oxide layer 166 and a substrate layer 168. It should be appreciated that waveguide 162, and other waveguides within the optical coupler, may comprise any desired forms of waveguides. It can be seen from the figure that the light received at λ₁ is dispersed in both directions 170a of the waveguide 162, while similarly light received at λ₂ is dispersed in both directions 170b, and light received at λ₃ is also dispersed in both directions 170c.

FIG. 16 illustrates a demultiplexer embodiment 190 configured for demultiplexing a plurality of wavelengths from a common waveguide. It will be noted that because of the reciprocity principle, the demultiplexer can have the same dimensions as the multiplexer described in FIG. 15. Based on the simulation results, the phase difference of the input light at each side of the coupler is optimally an integer multiple of 2π, which can be readily satisfied in response to tuning the distance between the couplers. By way of example and not limitation, a set of typical dimensions for multiplexing of a 1.55 μm and 1.3 μm wavelength input. For a 1.55 μm coupler, HCG thickness is 0.7 μm, duty cycle η is 0.6, period λ is 0.744 μm; while for a 1.3 μm coupler, thickness is 0.84 μm, duty cycle η is 0.635, period λ is 0.581 μm.

In the demultiplexer embodiment 190, wavelengths 206a, 206b, and 206c of light along waveguide 198 having a waveguide layer 200, an insulating layer 202 and a substrate layer 204, are vertically coupled to HCG 192a, 192b, 192c having segments of grating material 194a, 194b, 194c and spaces 195a, 195b, 195c, over gap 196a, 196b, 196c, whereby in response to vertical optical coupling operation the three wavelengths (λ_{1,} λ₂, λ₃) are output vertically. It will be noted that the HCG elements are configured to be frequency selective and thus perform demultiplexing of signals from the waveguide.

It should be appreciated that the waveguide can be coupled to any desired optical elements, such as optical fiber ports or other optical devices without limitation. In particular, in the case of a multiplexer, the various wavelengths coupled into the waveguide can be passed to an optical fiber port wherein they are coupled for communication over an optical fiber.

3.3. Vertical to Single Side Coupler

The phases of HCG modes are significantly influenced by high index material width. By chirping the grating, that is by changing the periodicity of the grating, the coupling from surface normal incidence can have a directional preference to the in-plane waveguide.

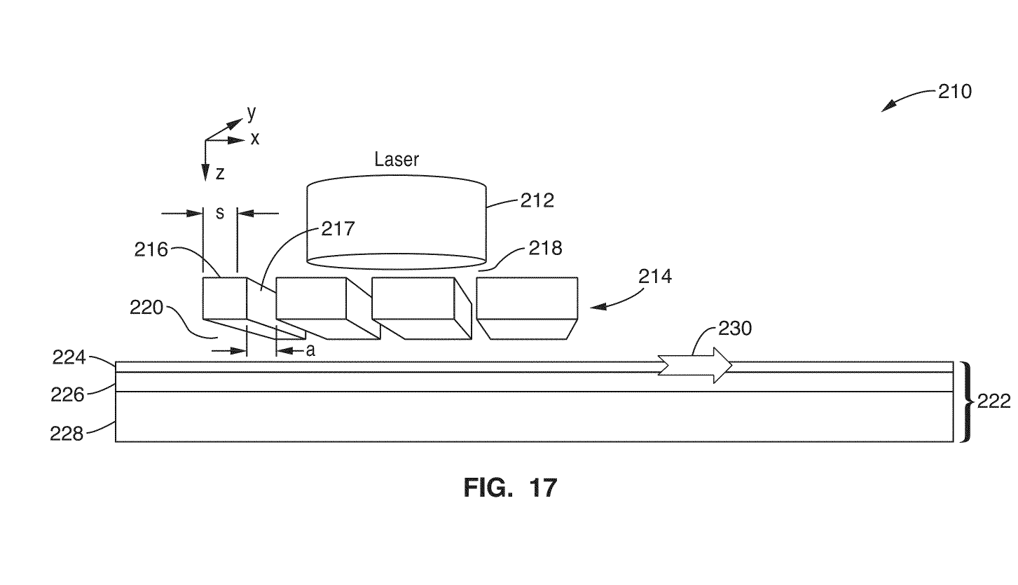

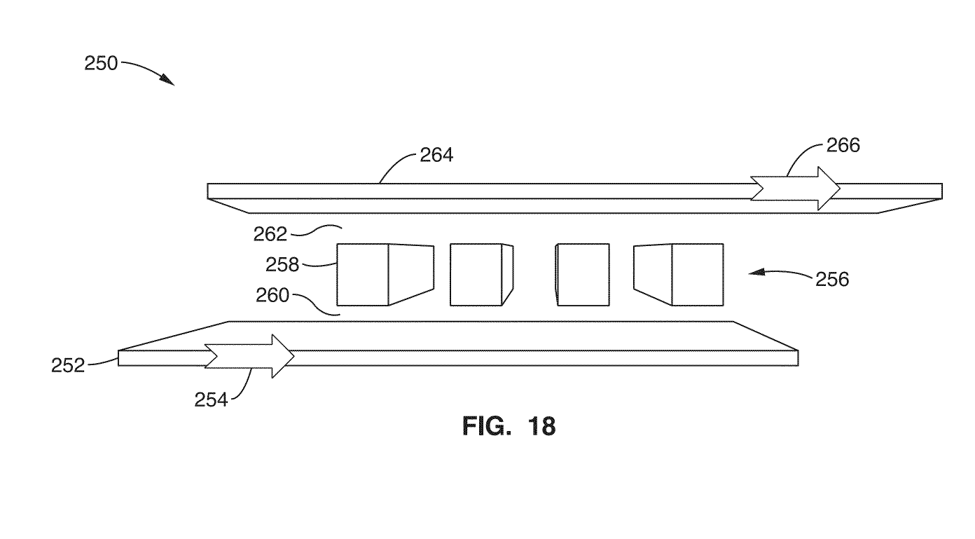

FIG. 17 illustrates a vertical to single side coupling embodiment 210 utilizing a chirped grating. Light can be directed from a laser light source 212, depicted as VCSEL, through gap 218 to an HCG 214, having segments of grating material 216 of different widths and/or spacing 217, and coupled through gap 220 to a waveguide 222 having a waveguide layer 224, an insulating layer 226 and a substrate layer 228. It can be seen in the figure that the light 230 from the light source, VCSEL 212, is shown traversing the waveguide in a single direction 230 in response to the chirp of the HCG whose grating bar width (s) and gap width (a) are chirped in the x direction to give a phase preference in that direction, thus providing a selection of coupling direction.

3.4. Parallel Waveguide Coupler

FIG. 18 illustrates an embodiment 250 of utilizing an HCG coupler to couple the light wave between two parallel waveguides. The HCG coupler 256 is located between two parallel waveguides 252, 264. Light from the input waveguide 252 along a first direction 254 is coupled through HCG 256 through gaps 260, 262 to waveguide 264 wherefrom light continues traveling along in a second direction 266 parallel to said first direction 254.

3.5. Reflector and Coupler for Surface-Emitting Lasers with In-Plane Waveguide and Active Region

An HCG vertical coupler and reflector can also be utilized in fabricating in-plane lasers emitting in the surface-normal direction. This is particularly useful for devices where mirrors are hard to construct (e.g., such as due to lack of suitable material or processing techniques) and/or surface emission is desirable for two-dimensional integration and on-wafer testing. One example is quantum cascade lasers (QCL) and a second example may be GaN or ZnO2 based devices.

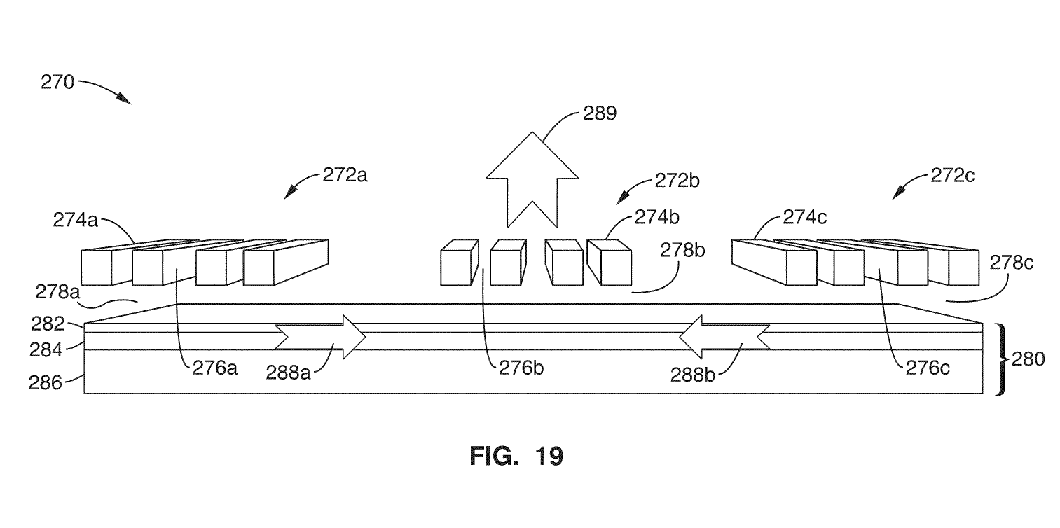

FIG. 19 illustrates an example surface-emitting QCL structure embodiment 270. HCG reflectors are shown 272a, 272c, having segments of grating material 274a, 274c, and spaces 276a, 276c, and located at two ends of waveguide 280 comprising a waveguide layer 282, insulating layer 284 and substrate layer 286, act as cavity mirrors with spacing 278a, 278c over waveguide 280. An HCG vertical coupler 272b having segments of grating material 274b and spaces 276b disposed over gap 278b from waveguide 280, is upon the active waveguide region to provide the vertical emitting 289 from the combination of light waves 288a, 288b. Similar to the structure in previous sections, the reflector and coupler can have identical thickness. In this case, a monolayer HCG can solve both vertical emitting and cavity reflection issues.

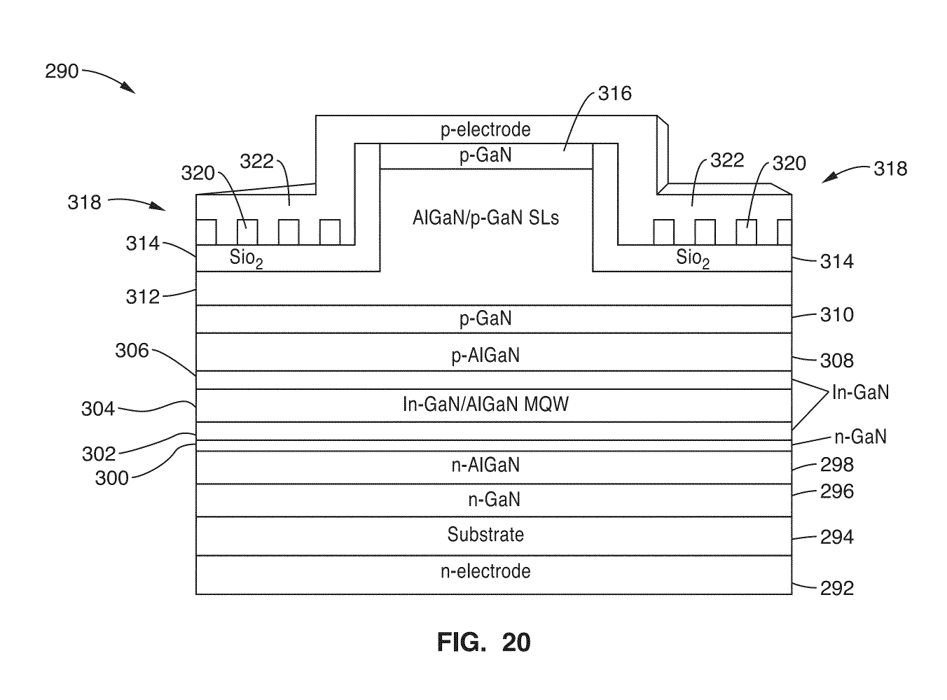

FIG. 20 illustrates the utilization of the HCG reflector within a GaN laser, exemplified by a GaN laser embodiment 290. GaN material system based laser diodes are of particular interest in recent times because of their short wavelength outputs. However, the etching of GaN facets always poses a difficulty. The implementation of the HCG reflector in a GaN laser structure provide a beneficial alternative to fabrication of the facets. The GaN laser is exemplified as having an n-electrode 292 beneath substrate 294, such as of sapphire or GaN material. Over the substrate is an n-GaN layer 296, an n-ALGaN layer 298, another n-GaN layer 300, an In-GaN layer 302, a quantum structure layer 304, such as comprising a multiple quantum well (MQW) layer, of InGaN/AlGaN within an active region, another In-GaN layer 306, a p-AlGaN layer 308 and a p-GaN layer 310. It should be appreciated that the active region may comprise quantum wells, quantum wires, quantum dots, either separately or in combination, or even a bulk region.

At the upper portion of the device there is stopper layers (SLs) 312 of AlGaN/p-GaN. Shoulders of SiO₂ in layer 314 flank a vertical portion of layer 312 of AlGaN/p-GaN, which is capped with a layer of p-GaN 316. An HCG 318 is integrated on the flanks of the vertical portions of layer 312 with grating segments 320 within a p-electrode layer 322. It will be appreciated that HCGs 318 are sitting at two edges of the laser diode acting as the reflector of the GaN laser cavity, while SiO₂ layer 314 is the low index gap between HCG and the semiconductor in the cavity. The HCG reflectors 318 are incorporated within the laser heterostructure to confine the light mode in the active region between the two HCG reflectors, so that device edges do not require special treatments, such as etching and reflective coating. If surface-normal emission is desirable, a vertical output coupler can also be made on the laser, similar to that of FIG. 18.

3.6. LED Coupling

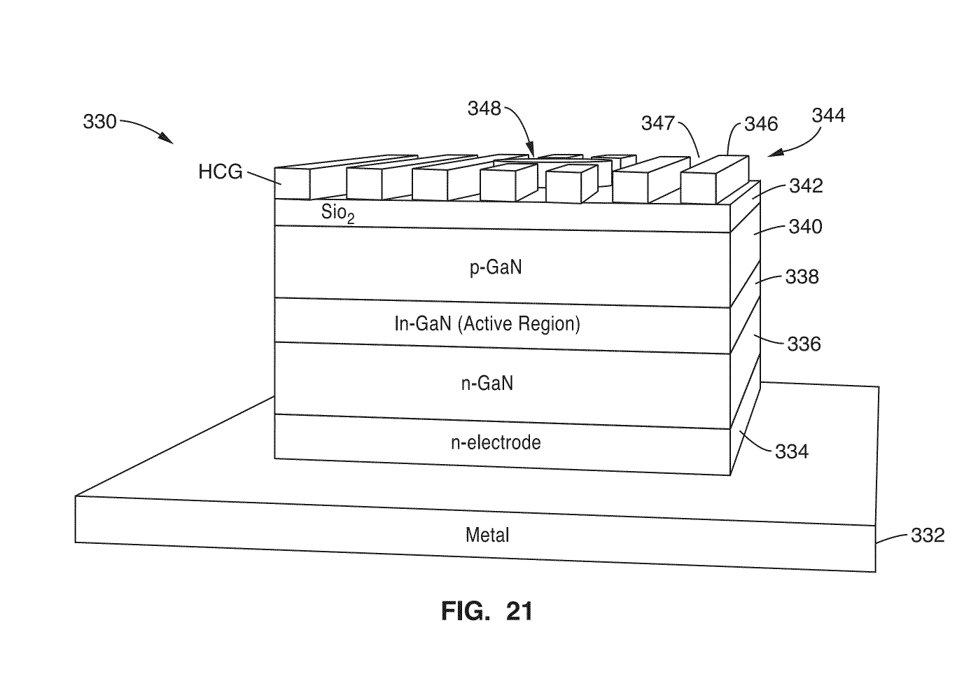

FIG. 21 illustrates an example embodiment 330 of a GaN light emitting diode incorporating an HCG vertical coupler on the active region. The light extraction efficiency for GaN based light emitting diodes has been an ongoing obstacle to the advance of LED efficiency, which without special treatment is only around 4%. One method to improving this light extraction efficiency is to roughen the emitting surface. However, utilizing the present invention optical coupling light extraction efficiency is dramatically increased.

The example LED embodiment 330 is shown fabricated with a metal base 332, upon which is an n-electrode layer 334, a layer of n-GaN 336, above which is an active region of InGaN 338 followed by a layer of p-GaN 340, a layer of SiO₂ 342, above which is an HCG layer 344 having grating segments 346 and spaces 347, and a p-electrode 348 disposed centrally. It is preferable that the central p-electrode be of a heavily doped material to inject the current. It goes through SiO₂ layer 342 and connect to p-GaN layer 340.

It should also be noted that the shape depicted in the top plane view of FIG. 21 is not necessarily constricted, but is dependent on how the LED is designed. Typically, the shape of the p-electrode is as a circle or a ring. It will be appreciated that the above describes an improvement to conventional GaN diodes, whose operating principles need not be discussed in detail as they are well known in the art.

3.7. Solar Cells

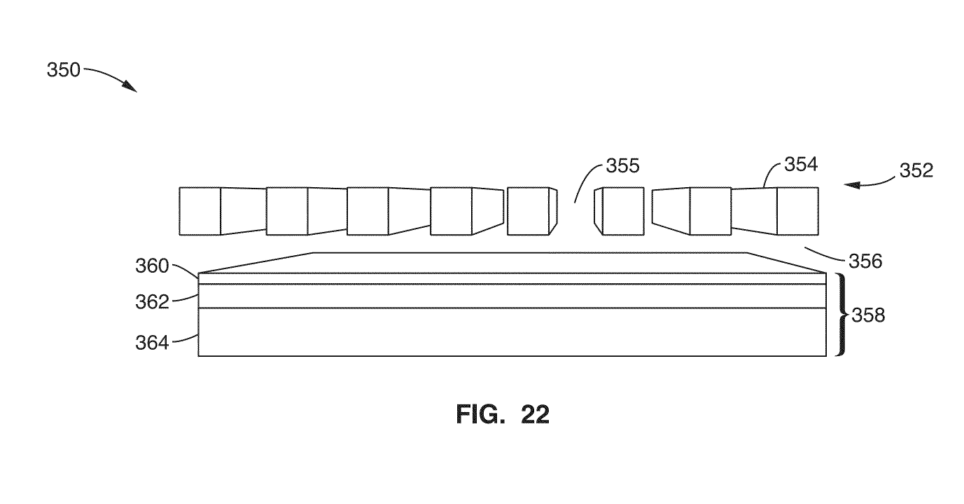

FIG. 22 illustrates an example solar cell embodiment 350, incorporating an HCG vertical coupler 352 with respect to a solar cell instead of a waveguide. The HCG 352 comprises segments of grating material 354 and spaces 355, positioned with a gap 356 over a solar cell 358 acting as a light collector, and shown comprising a p-n junction layers 360, 362 on a substrate 364. The incorporation of the HCG vertical coupler increases solar cell efficiency by reducing light reflection, because of the resonant nature of HCG in this configuration the light can be confined in the active region and therefore help to enhance efficiency

3.9. Use of Different Materials

The material requirement for an HCG coupler and reflector are readily achieved using a wide range of materials, as any material combinations can be utilized in which the refractive index of the grating materials have a high contrast with refractive index of the surrounding materials. The larger the contrast, the better the performance (bandwidth, coupling efficiency, and so forth) of the HCG coupler and reflector. Some possible materials include Si, Ge, GaAs, InAs, AlSb, InP, AlGalnP, InGaAs, AlGaAs, AlAs, CaSe, ZnSe, GaSb, AlSb, GaN, and similar dielectric materials.

From the discussion above it will be appreciated that the invention can be embodied in various ways, including the following:

1. An apparatus for optical coupling, comprising: a sub-wavelength high contrast grating (HCG) having a plurality of separate spaced apart segments of material with a gap between adjacent segments; and an optical waveguide proximally coupled through a selected gap to said sub-wavelength high contrast grating (HCG); wherein light is coupled between normal incidence on said sub-wavelength high contrast grating (HCG) and transmission through said optical waveguide.

2. The embodiment of claim 1, wherein said spaced apart segments of material of said high contrast grating (HCG) comprise a high refractive index material surrounded by low index material.

3. The embodiment of claim 1, wherein the index of refraction of said high index material and the index of refraction of said low index material have a differential that is greater than one unit.

4. The embodiment of claim 1, wherein said spaced apart segments of material comprising said high contrast grating have a width (s), thickness (t), a spacing (a) between segments, and a period Λ.

5. The embodiment of claim 1, wherein said optical waveguide comprises a slab waveguide, HCG, or hollow-core waveguides (HW).

6. The embodiment of claim 1, wherein said sub-wavelength high contrast grating (HCG) can be chirped to support asymmetrical waveguide transmission.

7. The embodiment of claim 1, further comprising an in-plane reflector for preventing transmission along selected directions of angular displacement of said light.

8. The embodiment of claim 1, wherein said optical coupler comprises a multiplexer or demultiplexer for coupling, through an angular displacement, a number of wavelengths of light between a normal incident direction to said HCG and transmission through said waveguide.

9. The embodiment of claim 1, wherein said apparatus comprises materials selected from the group of materials consisting of Si, Ge, GaAs, InAs, InAlGaAs, AlAs, AlSb, GaSb, GaAlSb, InP, AlGalnP, InGaAlAs, CdSe, ZnSe, CdSSe, InAlGaN, InN, AlN, GaN, ZnO2, and SiN.

10. The embodiment of claim 1, wherein said optical coupling is integrated within the surface of a light emitting diode to transfer light reaching the waveguide along the surface to a vertical output.

11. The embodiment of claim 1, wherein said optical coupling is integrated within the surface of a solar cell to transfer light impinging on the surface into the p-n junction taking the place of a waveguide along said surface.

12. An apparatus for optical coupling, comprising: a sub-wavelength high contrast grating (HCG) having a plurality of separate spaced apart segments of material with a gap between adjacent segments; wherein said spaced apart segments of material comprise a high refractive index material surrounded by low index material;wherein the index of refraction of said high index material and the index of refraction of said low index material have a differential that is greater than one unit; and an optical waveguide proximally coupled through a selected gap to said sub-wavelength high contrast grating (HCG); wherein light is coupled between normal incidence on said sub-wavelength high contrast grating (HCG) and transmission through said optical waveguide

13. The embodiment of claim 12, wherein said waveguide comprises a slab waveguide, HCG, or hollow-core waveguides (HW).

14. The embodiment of claim 12, wherein said sub-wavelength high contrast grating (HCG) of said optical coupler can be chirped to support asymmetrical waveguide transmission.

15. The embodiment of claim 12, further comprising an in-plane reflector for preventing transmission along selected directions of angular displacement of said light.

16. The embodiment of claim 12, wherein said apparatus comprises materials selected from the group of materials consisting of Si, Ge, GaAs, InAs, InAlGaAs, AlAs, AlSb, GaSb, GaAlSb, InP, AlGalnP, InGaAlAs, CdSe, ZnSe, CdSSe, InAlGaN, InN, AlN, GaN, ZnO2, and SiN.

17. An apparatus for multiplexing or demultiplexing optical signals, comprising: a plurality of sub-wavelength high contrast gratings (HCGs), each having a plurality of separate spaced apart segments of material with a gap between adjacent segments; and an optical waveguide proximally coupled through a selected gap to said plurality of sub-wavelength high contrast gratings (HCGs); wherein light received by each of said sub-wavelength high contrast gratings (HCGs) is multiplexed onto said optical waveguide; and wherein light received by said optical waveguide is demultiplexed through said plurality of sub-wavelength high contrast gratings (HCGs) which contain sub-wavelength high contrast gratings (HCGs) that are adapted to pass different wavelengths of said light.

18. A surface-emitting quantum cascade laser apparatus, comprising:

an active region having quantum wells; a reflector on either side of said active region; and at least two reflective sub-wavelength high contrast gratings (HCGs) near an output the surface-emitting laser to confine the light mode in an active region of the laser between two HCG reflectors.

19. A light emitting diode apparatus, comprising: an n-electrode region; a p-electrode region; an active region disposed between said n-electrode region and said p-electrode region; and an optical coupler disposed on an output of said light emitting diode and comprising a waveguide layer for collecting light in a horizontal plane and coupled with a sub-wavelength high-contrast grating for redirecting collected light for output in a vertical direction.

20. A solar cell apparatus, comprising: a sub-wavelength high contrast grating (HCG) having a plurality of separate spaced apart segments of material; and a solar cell having layers of a p-n junction upon which light from said HCG is directed and converted to electrical energy.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

What is claimed is:

1. An apparatus for optical coupling, comprising:
a sub-wavelength high contrast grating (HCG) having a plurality of separate spaced apart segments of material with a gap between adjacent segments; and
an optical waveguide proximally coupled through a selected gap to said sub-wavelength high contrast grating (HCG);
wherein light is coupled between normal incidence on said sub-wavelength high contrast grating (HCG) and transmission through said optical waveguide.

2. The apparatus recited in claim 1, wherein said spaced apart segments of material of said high contrast grating (HCG) comprise a high refractive index material surrounded by low index material.

3. The apparatus recited in claim 1, wherein the index of refraction of said high index material and the index of refraction of said low index material have a differential that is greater than one unit.

4. The apparatus recited in claim 1, wherein said spaced apart segments of material comprising said high contrast grating have a width (s), thickness (t), a spacing (a) between segments, and a period Λ.

5. The apparatus recited in claim 1, wherein said optical waveguide comprises a slab waveguide, HCG, or hollow-core waveguides (HW).

6. The apparatus recited in claim 1, wherein said sub-wavelength high contrast grating (HCG) can be chirped to support asymmetrical waveguide transmission.

7. The apparatus recited in claim 1, further comprising an in-plane reflector for preventing transmission along selected directions of angular displacement of said light.

8. The apparatus recited in claim 1, wherein said optical coupler comprises a multiplexer or demultiplexer for coupling, through an angular displacement, a number of wavelengths of light between a normal incident direction to said HCG and transmission through said waveguide.

9. The apparatus recited in claim 1, wherein said apparatus comprises materials selected from the group of materials consisting of Si, Ge, GaAs, InAs, InAlGaAs, AlAs, AlSb, GaSb, GaAlSb, InP, AlGalnP, InGaAlAs, CdSe, ZnSe, CdSSe, InAlGaN, InN, AlN, GaN, ZnO2, and SiN.

10. The apparatus recited in claim 1, wherein said optical coupling is integrated within the surface of a light emitting diode to transfer light reaching the waveguide along the surface to a vertical output.

11. The apparatus recited in claim 1, wherein said optical coupling is integrated within the surface of a solar cell to transfer light impinging on the surface into the p-n junction taking the place of a waveguide along said surface.

12. An apparatus for optical coupling, comprising:
a sub-wavelength high contrast grating (HCG) having a plurality of separate spaced apart segments of material with a gap between adjacent segments;
wherein said spaced apart segments of material comprise a high refractive index material surrounded by low index material;
wherein the index of refraction of said high index material and the index of refraction of said low index material have a differential that is greater than one unit; and
an optical waveguide proximally coupled through a selected gap to said sub-wavelength high contrast grating (HCG);
wherein light is coupled between normal incidence on said sub-wavelength high contrast grating (HCG) and transmission through said optical waveguide

13. The apparatus recited in claim 12, wherein said waveguide comprises a slab waveguide, HCG, or hollow-core waveguides (HW).

14. The apparatus recited in claim 12, wherein said sub-wavelength high contrast grating (HCG) of said optical coupler can be chirped to support asymmetrical waveguide transmission.

15. The apparatus recited in claim 12, further comprising an in-plane reflector for preventing transmission along selected directions of angular displacement of said light.

16. The apparatus recited in claim 12, wherein said apparatus comprises materials selected from the group of materials consisting of Si, Ge, GaAs, InAs, InAlGaAs, AlAs, AlSb, GaSb, GaAlSb, InP, AlGalnP, InGaAlAs, CdSe, ZnSe, CdSSe, InAlGaN, InN, AlN, GaN, ZnO2, and SiN.

17. An apparatus for multiplexing or demultiplexing optical signals, comprising:
a plurality of sub-wavelength high contrast gratings (HCGs), each having a plurality of separate spaced apart segments of material with a gap between adjacent segments; and
an optical waveguide proximally coupled through a selected gap to said plurality of sub-wavelength high contrast gratings (HCGs);
wherein light received by each of said sub-wavelength high contrast gratings (HCGs) is multiplexed onto said optical waveguide; and
wherein light received by said optical waveguide is demultiplexed through saidplurality of sub-wavelength high contrast gratings (HCGs) which contain sub-wavelenghth high contrast gratings (HCGs) that are adapted to pass different wavelengths of said light.

18. A surface-emitting quantum cascade laser apparatus, comprising:
an active region having quantum wells;
a reflector on either side of said active region; and
at least two reflective sub-wavelength high contrast gratings (HCGs) near an output the surface-emitting laser to confine the light mode in an active region of the laser between two HCG reflectors.

19. A light emitting diode apparatus, comprising:
an n-electrode region;
a p-electrode region;
an active region disposed between said n-electrode region and said p-electrode region; and
an optical coupler disposed on an output of said light emitting diode and comprising a waveguide layer for collecting light in a horizontal plane and coupled with a sub-wavelength high-contrast grating for redirecting collected light for output in a vertical direction.

20. A solar cell apparatus, comprising:
a sub-wavelength high contrast grating (HCG) having a plurality of separate spaced apart segments of material; and
a solar cell having layers of a p-n junction upon which light from said HCG is directed and converted to electrical energy.
